(19) United States
(12) Patent Application Publication
(10) Pub. No.: US 2026/0107514 A1
(43) Pub. Date: Apr. 16, 2026

(54) TRANSISTOR AND DISPLAY APPARATUS INCLUDING THE SAME

(71) Applicant: LG Display Co., Ltd., Seoul (KR)

(72) Inventors: Jeong Yeop LEE, Paju-si (KR); Jung Seok SEO, Paju-si (KR); Kyung Chul OK, Paju-si (KR); Woo Seok JEONG, Paju-si (KR); Jong Ho KIM, Paju-si (KR)

(73) Assignee: LG Display Co., Ltd., Seoul (KR)

(21) Appl. No.: 19/315,233

(22) Filed: Aug. 29, 2025

(30) Foreign Application Priority Data
Oct. 14, 2024 (KR) 10-2024-0139703

(51) Int. Cl. H10D 30/67; H10D 86/40; H10D 86/60; H10K 59/121

(52) U.S. Cl. CPC H10D 30/6736; H10D 30/6731; H10D 30/6755; H10D 30/6757; H10D 86/423; H10D 86/431; H10D 86/60; H10K 59/1213

(57) ABSTRACT

A transistor and a display apparatus including the same are provided. The display apparatus includes a substrate including an active area and a non-active area. A first transistor is disposed in the active area and includes a first gate electrode, a first-a source drain electrode, a first-b source drain electrode, and a first active layer. A first gate insulation layer is disposed between the first gate electrode and the first active layer. The first gate insulation layer includes a first portion, disposed adjacent to an edge outer portion of the first gate electrode and not overlapping the gate electrode, and a second portion, disposed overlapping the first gate electrode. The thickness of the first portion differs from the thickness of a second portion. By adjusting the gate insulation thickness, the structure may help control dopant distribution and enhance the electrical stability and reliability of the first transistor.

### CROSS-REFERENCE TO RELATED APPLICATIONS

This application claims the benefit of the Korean Patent Application No. 10-2024-0139703 filed on Oct. 14, 2024, which is hereby incorporated by reference as if fully set forth herein.

### BACKGROUND

### Technical Field

The present disclosure relates to a transistor and a display apparatus including the same, and more particularly, to a transistor and a display apparatus including the same, which may enhance reliability.

### Description of the Related Art

In televisions (TVs), monitors, smartphones, tablet personal computers (PCs), and notebook computers, display apparatuses displaying an image are being used in various modes and types.

Display apparatuses include a display panel, which includes a plurality of light emitting devices for implementing an image and a transistor for controlling an operation of each of the light emitting devices or an operation of a liquid crystal, and intactly display an image which is to be displayed through the plurality of light emitting devices or the liquid crystal.

Display apparatuses include a plurality of pixels and include a plurality of driving and switching elements for driving and controlling the pixels. The driving and switching elements may each be configured as a transistor, and the transistors are being widely applied to integrated circuits as well as pixels.

Recently, various research and developments for enhancing the performance and reliability of transistors are being done.

### BRIEF SUMMARY

The disclosure relates to a transistor structure in which the gate insulation layer has different thicknesses across distinct regions, including the central area beneath the gate electrode, the edge adjacent to the gate, and the outer portions. This variation in thickness is used to control the implantation depth of dopants, enabling the peak concentration of dopants to be positioned in a non-active layer such as the gate insulation layer or buffer layer. By preventing the peak dopant concentration from entering the channel region, the structure reduces threshold voltage shift and minimizes the reduction of the effective channel length caused by thermal diffusion.

This approach is especially useful for switching transistors that have shorter channels, where dopant diffusion has a more pronounced effect on electrical performance. In contrast, driving transistors with longer channels are less affected and can maintain a uniform gate insulation thickness. The described structure allows electrical characteristics to be selectively controlled between different transistor types without requiring additional elements or process complexity.

The described configuration permits both switching and driving transistors to be formed using common materials and processing steps while achieving distinct electrical profiles through physical design and doping control. This supports improved reliability and lower power consumption in the display apparatus and facilitates efficient manufacturing practices that reduce process steps and material use, contributing to environmental and operational advantages.

For example, embodiments of the present disclosure provide a transistor and a display apparatus including the same, which may enhance reliability.

Embodiments of the present disclosure provide a display apparatus in which a reduction in length of a valid channel may be prevented when forming a transistor including an oxide semiconductor, and thus, a threshold voltage (Vth) of a transistor may be prevented from being shifted in a negative (−) direction at an initial stage.

To this end, embodiments of the present disclosure provide a transistor and a display apparatus including the same, in which a thickness of a gate insulation layer may be differently set, a peak of a Gaussian distribution of dopants may be controlled to be disposed in a layer which differs from an active layer, and a length of a valid channel may be prevented from being reduced by the diffusion of dopants based on thermal treatment.

Therefore, embodiments of the present disclosure may not add a separate element and may differently set a thickness of a gate insulation layer, and thus, may enhance the driving stability and reliability of a transistor and a display apparatus and may decrease power consumption, thereby implementing environment, social, and governance (ESG).

To achieve these technical benefits and other advantages and in accordance with the purpose of the disclosure, as embodied and broadly described herein, a display apparatus includes: a substrate including an active area and a non-active area, a first transistor disposed in the active area and including a first gate electrode, a first-a source drain electrode, a first-b source drain electrode, and a first active layer, and a first gate insulation layer disposed between the first gate electrode and the first active layer, wherein a thickness of a first portion, which does not overlap the first gate electrode and is adjacent to an edge outer portion of the first gate electrode, differs from a thickness of a second portion overlapping the first gate electrode in the first gate insulation layer.

In the first gate insulation layer, a thickness of a third portion which is disposed outside the first portion and overlaps the first active layer may differ from a thickness of the first portion.

The first active layer may include a source drain region where a dopant is doped in a region which does not overlap the first gate electrode, and in a region overlapping the first portion, a peak of a Gaussian distribution of a doping concentration of the dopant is disposed in a layer which may differ from the first active layer.

A thickness of the first portion may be greater than a thickness of the second portion, and a thickness of the third portion may be less than the thickness of the first portion, and the first gate insulation layer may have a peak of a Gaussian distribution of dopants doped on the first active layer in the first portion.

In the first active layer, a peak of a Gaussian distribution of dopants doped on the first active layer may be disposed at a portion spaced apart from an edge of the first gate electrode by the first portion.

The thickness of the first portion may be greater than the thickness of the second portion and may be less than a sum of thicknesses of the second portion and the first gate electrode.

The display apparatus may further include a first buffer layer between the substrate and the first active layer, wherein a thickness of the first portion may be less than a thickness of the second portion, a thickness of the third portion may be greater than the thickness of the first portion, and the first buffer layer may have a peak of a Gaussian distribution of dopants doped on the first active layer in a region overlapping the first portion.

The thickness of the first portion may be less than the thickness of the second portion and may be greater than 1/10 of the thickness of the second portion.

The first active layer may include an oxide semiconductor.

The display apparatus may further include a second transistor disposed in the active area and including a second gate electrode, a second-a source drain electrode, a second-b source drain electrode, and a second active layer, wherein a length of a channel formed in the first active layer in the first transistor may be shorter than a length of a channel formed in the second active layer in the second transistor.

The display apparatus may further include a second gate insulation layer disposed between the second gate electrode and the second active layer, wherein a thickness of a portion, disposed outside the second gate electrode not to overlap each other, may be equal to a thickness of a portion disposed at a portion overlapping the second gate electrode in the second gate insulation layer.

A position of a maximum peak of a Gaussian distribution of dopants doped on the first transistor may differ from a position of a maximum peak of a Gaussian distribution of dopants doped on the second transistor.

A position, at which a maximum peak is formed in a Gaussian distribution of dopants doped on the first transistor, may be disposed in a layer which differs from the first active layer, and a position, at which a maximum peak is formed in a Gaussian distribution of dopants doped on the second transistor, may be disposed in the second active layer.

The display apparatus may further include a light emitting device disposed on the first and second transistors in the active area and including a first electrode, an organic emission layer, and a second electrode, and one of the first and second transistors may be electrically connected to the first electrode.

In another aspect of the present disclosure, a transistor includes a first active layer including an oxide semiconductor material and including a channel region and a first-a source drain region and a first-b source drain region provided with the channel region therebetween, a gate electrode disposed on the first active layer to overlap the first channel region, a first-a source drain electrode and a first-b source drain electrode respectively connected to the first-a source drain region and the first-b source drain region, and a first gate insulation layer disposed between the first gate electrode and the first active layer, wherein a thickness of a first portion, which does not overlap the first gate electrode and is adjacent to an edge of the first gate electrode, differs from a thickness of a second portion disposed at a portion overlapping the first gate electrode in the first gate insulation layer.

A thickness of a third portion, which is disposed outside the first portion and overlaps the first active layer, may differ from a thickness of the first portion in the first gate insulation layer.

Dopants may be doped in the first-a and first-b source drain regions in the first active layer, and in a region overlapping the first portion, a peak of a Gaussian distribution of a doping concentration of the dopants may be disposed in a layer which differs from the first active layer.

A thickness of the first portion may be greater than a thickness of the second portion, a thickness of the third portion may be less than the thickness of the first portion, and the first gate insulation layer may have a peak of a Gaussian distribution of dopants doped on the first active layer in the first portion.

In the first active layer, a peak of a Gaussian distribution of dopants doped on the first active layer may be disposed at a portion spaced apart from an edge of the first gate electrode by the first portion.

The transistor may further include a first buffer layer between the substrate and the first active layer, wherein a thickness of the first portion may be less than a thickness of the second portion, a thickness of the third portion may be greater than the thickness of the first portion, and the first buffer layer may have a peak of a Gaussian distribution of dopants doped on the first active layer in a region overlapping the first portion.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram for describing an embodiment of a display apparatus applicable to the present disclosure;

FIG. 2 is a diagram for describing an embodiment of a circuit diagram of a subpixel applicable to a display apparatus according to the present disclosure;

FIG. 3 is a cross-sectional view for describing a first embodiment of a transistor applicable to a first transistor corresponding to a switching transistor in FIG. 2;

FIG. 4 is a cross-sectional view for describing a second embodiment of a transistor applicable to a first transistor corresponding to a switching transistor in FIG. 2;

FIG. 5 is a cross-sectional view for describing an embodiment of a transistor applicable to a second transistor corresponding to a driving transistor in FIG. 2;

FIG. 6 is a diagram for describing a process of forming a channel region of a transistor;

FIG. 7 is a diagram for describing a dopant concentration formed in the second transistor described with reference to FIG. 5;

FIG. 8 is a diagram for describing a dopant concentration formed in the first transistor according to the first embodiment described with reference to FIG. 3;

FIG. 9 is a diagram for describing a dopant concentration formed in the first transistor according to the second embodiment described with reference to FIG. 4; and

FIG. 10 is a diagram for describing an embodiment of a display apparatus to which first and second transistors are applied.

### DETAILED DESCRIPTION

Hereinafter, embodiments will be described in detail with reference to the accompanying drawings.

Like reference numerals refer to like elements. Also, a thickness, a ratio, and a dimension of each element described herein are illustrated to be partially enlarged or reduced for convenience of effective description. A scale of each element illustrated in the drawings of the present disclosure may have a scale which differs from a real scale, for convenience of description, but is not limited to a scale illustrated in the drawings.

In the present disclosure, when an arbitrary element (or a region, a layer, a portion, etc.) is described as “being on”, “connected”, or “coupled”, this may denote that the arbitrary element may be directly connected/coupled to another element, or a third element may be disposed therebetween.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “and/or” may include all of one or more combinations capable of being defined by relevant elements.

Terms like a first and a second may be used to describe various elements, but the elements should not be limited by the terms. The terms may be used only as object for distinguishing an element from another element. For example, without departing from the spirit and scope of the inventive concept, a first element may be referred to as a second element, and similarly, the second element may be referred to as the first element. The terms of a singular form may include plural forms unless referred to the contrary.

The terms “under”, “below”, “on”, and “above” may be used to describe a correlation between elements illustrated in the drawings. The terms may be a relative concept and may be described with respect to a direction illustrated in the drawings. For example, unless “just” or “direct” is used, one or more other elements between two elements may be disposed. Spatially relative terms “below”, “beneath”, “lower”, “above”, and “upper” may be used herein for easily describing a relationship between one device or elements and other devices or elements as illustrated in the drawings. Therefore, for example, “under” and “lower” may be opposite to “on” and “upper” with respect to a first element.

It should be understood that spatially relative terms are terms including different orientations of elements in use or operation, in addition to the orientation illustrated in the drawings. For example, if a device in the drawings is turned over, elements described as being on the “below” or “beneath” sides of other elements may be placed on “above” sides of the other elements. Therefore, the exemplary term “lower” may include both orientations of “lower” and “upper”. Likewise, the exemplary term “above” or “upper” may include both orientations of above and below.

It should be understood that the meaning of “include,” “comprise,” “including,” or “comprising,” specifies a property, a region, a fixed number, a step, a process, an element and/or a component, but does not exclude other properties, regions, fixed numbers, steps, processes, elements and/or components.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other, or may be carried out together in co-dependent relationship.

Hereinafter, a display apparatus according to an embodiment of the present disclosure will be described with reference to the accompanying drawings.

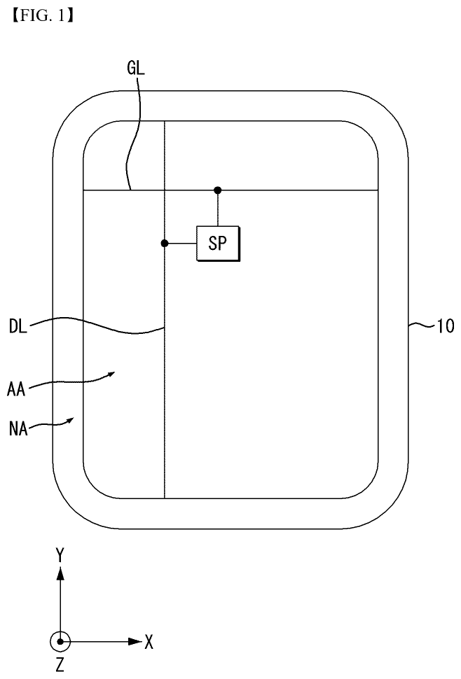

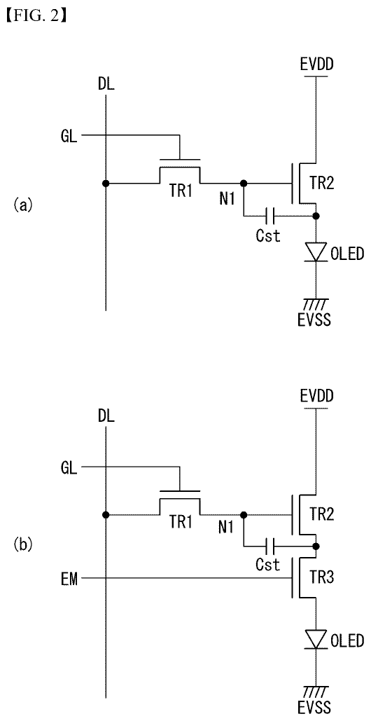

FIG. 1 is a diagram for describing an embodiment of a display apparatus applicable to the present disclosure, and FIG. 2 is a diagram for describing an embodiment of a circuit diagram of a subpixel applicable to a display apparatus according to the present disclosure.

Referring to FIGS. 1 and 2, a display apparatus according to an embodiment of the present disclosure may include a display panel 10, and the display panel 10 may include an active area AA and a non-active area NA.

The active area AA may be an area which displays an image. A plurality of subpixels SP may be disposed in the active area AA, and the active area AA may display an image by using the plurality of subpixels SP. An area where the plurality of subpixels SP are disposed may be the active area AA, and an area other than the active area AA may be the non-active area NA.

The non-active area NA may be disposed in an edge region surrounding the active area AA which displays an image. At least one driver for driving the plurality of subpixels SP may be disposed in the non-active area NA.

Various additional elements for driving the subpixels SP of the active area AA may be further disposed in the non-active area NA.

At least one subpixel SP among a plurality of pixels, for example, as illustrated in (a) or (b) of FIG. 2, may include a first transistor TR1, a second transistor TR2, a capacitor Cst, and a light emitting device OLED.

For example, the first transistor TR1 may be a switching transistor, and the second transistor TR2 may be a driving transistor.

A first electrode (for example, a drain electrode) of the first transistor TR1 may be electrically connected to a data line DL, a second electrode (for example, a source electrode) thereof may be electrically connected to a first node N1, and a gate electrode of the first transistor TR1 may be electrically connected to a gate line GL. The first transistor TR1 may transfer a data signal, supplied through the data line DL, to the first node N1 in response to a scan signal supplied through the gate line GL.

The capacitor Cst may be electrically connected to the first node N1 and may be charged with a voltage applied to the first node N1.

A first electrode (for example, a drain electrode) of the second transistor TR2 may be supplied with a high-level driving voltage EVDD, and a second electrode (for example, a source electrode) thereof may be electrically connected to a first electrode of the light emitting device OLED. The second transistor TR2 may control the amount of driving current flowing in the light emitting device OLED, based on a voltage applied to a gate electrode thereof.

An active layer of the first transistor TR1 and/or the second transistor TR2 may include oxide such as indium-gallium-zinc-oxide (IGZO), but is not limited thereto.

The light emitting device OLED may emit light corresponding to a driving current. The light emitting device OLED may emit light corresponding to one color of red, green, blue, and white.

The light emitting device OLED may include the anode electrode, an emission layer disposed on the anode electrode, and a cathode electrode supplying a common voltage. The emission layer may be implemented to emit light of the same color for each pixel, like white light, or may be implemented to emit lights of different colors for each subpixel SP, like red light, green light, or blue light.

The light emitting device OLED may be a diode of a top emission type, or may be a diode of a bottom emission type.

In (a) of FIG. 2, a case where the second transistor TR2 corresponding to a driving transistor is directly connected to the light emitting device OLED is illustrated for example, but the present disclosure is not limited thereto and as illustrated in (b) of FIG. 2, the second transistor TR2 may be connected to the light emitting device OLED through a third transistor TR3 which is a switching transistor.

In detail, as in (b) of FIG. 2, the third transistor TR3 may be disposed between the second transistor TR2 and the light emitting device OLED, a first electrode of the third transistor TR3 may be connected to the second electrode of the second transistor TR2, and a second electrode of the third transistor TR3 may be electrically connected to the first electrode of the light emitting device OLED. In response to an emission signal EM applied to the gate electrode of the second transistor TR2, the third transistor TR3 may control the on/off of the driving current applied from the second transistor TR2 to the light emitting device OLED.

Moreover, although not shown in (a) and (b) of FIG. 2, a compensation circuit for compensating for a threshold voltage of the second transistor TR2 corresponding to the driving transistor may be further included in the subpixel SP. The compensation circuit may include at least one transistor connected to the second transistor TR2 and may be provided in the subpixel SP.

Based on a configuration type, the compensation circuit may have a 3T1C structure where three transistors and one capacitor Cst are included in the subpixel SP, or a 4T2C structure where four transistors and two capacitors Cst are included in the subpixel SP, or various structures such as 5T2C, 6T1C, 6T2C, 7T1C, and 7T2C.

In the subpixel SP, due to a difference of purposes for controlling the second transistor TR2 which is a driving transistor and the first and third transistors which are switching transistors, a length of a channel may differ, or a thickness of a portion of a gate insulation layer disposed between a gate electrode and an active layer may differ. Hereinafter, this will be described in detail.

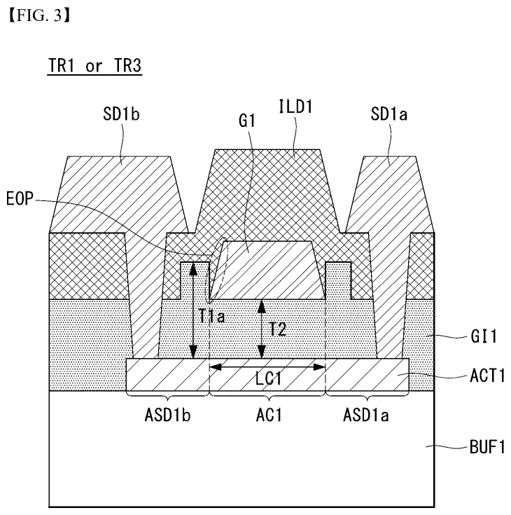

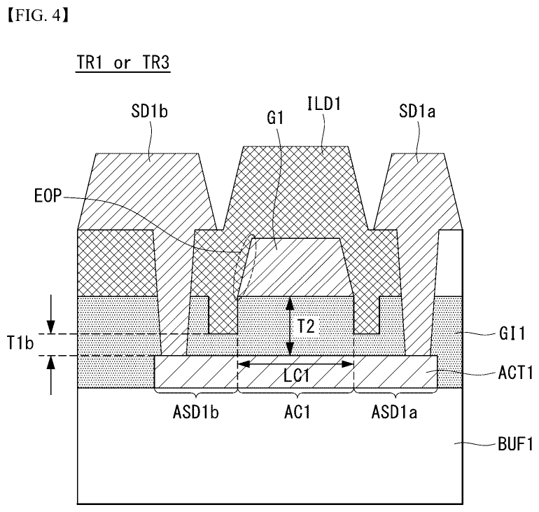

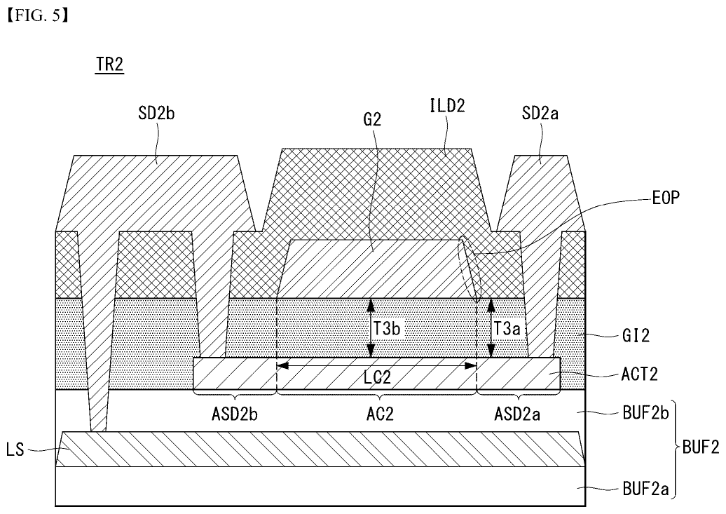

FIG. 3 is a cross-sectional view for describing a first embodiment of a transistor applicable to a first transistor corresponding to a switching transistor in FIG. 2, FIG. 4 is a cross-sectional view for describing a second embodiment of a transistor applicable to a first transistor corresponding to a switching transistor in FIG. 2, and FIG. 5 is a cross-sectional view for describing an embodiment of a transistor applicable to a second transistor corresponding to a driving transistor in FIG. 2.

A configuration of a transistor illustrated in FIGS. 3 and 4 may be applied to a switching transistor such as a first transistor TR1 or a third transistor TR3. The first transistor TR1 or the third transistor TR3, which is a switching transistor, may include a first gate electrode G1, a first active layer ACT1, a first-a source drain electrode SD1a, a first-b source drain electrode SD1b, a first gate insulation layer GI1, a first interlayer insulation layer ILD1, and a first buffer layer BUF1, which are disposed in the active area AA.

The first active layer ACT1 may include, for example, an oxide semiconductor material such as IGZO. The first active layer ACT1 may include a first channel region AC1 and a first-a source drain region ASD1a and a first-b source drain region ASD1b which are disposed with the first channel region AC1 therebetween.

The first channel region AC1 may be disposed at a portion overlapping the first gate electrode G1, and the first-a source drain region ASD1a and the first-b source drain region ASD1b may be disposed in a region which does not overlap the first gate electrode G1, outside the first channel region AC1.

The first channel region AC1 may have a doping concentration of dopants which is relatively lower than that of each of the first-a source drain region ASD1a and the first-b source drain region ASD1b and may have an electrical conductivity corresponding to a voltage applied to the first gate electrode G1, and a channel enabling a carrier to move may be formed based on the application of a voltage.

The first-a source drain region ASD1a and the first-b source drain region ASD1b may be relatively higher in doping concentration of dopants than the first channel region AC1, and thus, may each be formed of a conductive region which is high in electrical conductivity.

The first channel region AC1 may have a first channel length LC1 between the first-a source drain region ASD1a and the first-b source drain region ASD1b and may have a length which is less than a second channel length LC2 of a second channel region AC2 of a second transistor TR2 described below.

The first gate electrode G1 may be disposed apart from the first active layer ACT1 and may overlap the first channel region AC1. The first gate electrode G1 may include a conductive material. For example, the first gate electrode G1 may include metal such as aluminum (Al), chrome (Cr), copper (Cu), titanium (Ti), molybdenum (Mo), and tungsten (W). The first gate electrode G1 may be insulated from the first active layer ACT1 by the first gate insulation layer GI1.

The first gate insulation layer GI1 may be disposed between the first gate electrode G1 and the first active layer ACT1 for insulation between the first gate electrode G1 and the first active layer ACT1 and may include at least one of silicone oxide (SiOx), silicone nitride (SiNx), and silicone oxynitride (SiOxNy). For example, SiOx may include silicone dioxide (SiO₂).

The first interlayer insulation layer ILD1 may be disposed on the first gate electrode G1. The first interlayer insulation layer ILD1 may extend to an outer portion of the first gate electrode G1. A side surface of the first gate electrode G1 may be covered by the first interlayer insulation layer ILD1. The first interlayer insulation layer ILD1 may extend along the first gate insulation layer GI1. The first interlayer insulation layer ILD1 may include an insulating material. For example, the first interlayer insulation layer ILD1 may include SiOx or SiOxNy.

Each of the first-a source drain electrode SD1a and the first-b source drain electrode SD1b may be disposed on the first interlayer insulation layer ILD1, and the first-a source drain electrode SD1a and the first-b source drain electrode SD1b may pass through a portion of the first interlayer insulation layer ILD1 and may respectively contact the first-a source drain region ASD1a and the first-b source drain region ASD1b. Each of the first-a source drain electrode SD1a and the first-b source drain electrode SD1b may be insulated from the first gate electrode G1 by the first interlayer insulation layer ILD1.

Each of the first-a source drain electrode SD1a and the first-b source drain electrode SD1b may include at least one of metals such as Al, Cr, Cu, Ti, Mo, and W and may include a material which differs from that of the first gate electrode G1.

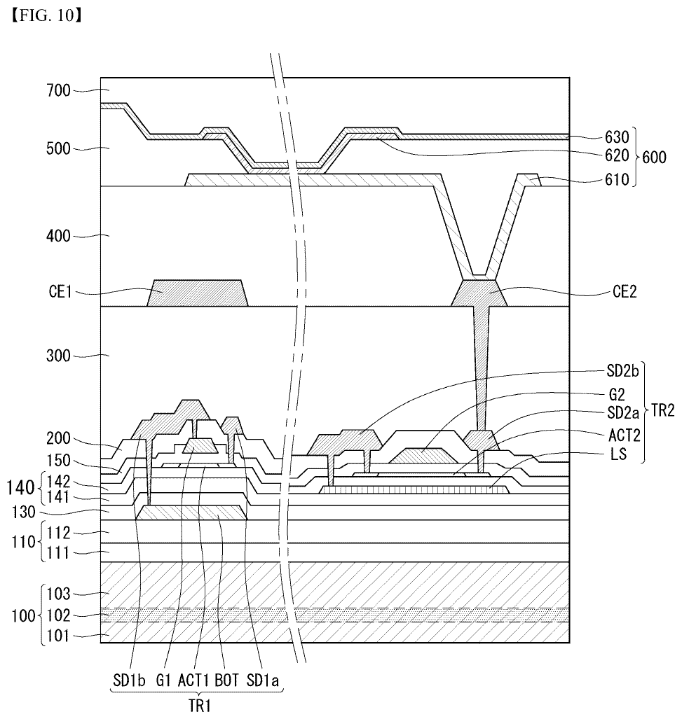

The first buffer layer BUF1 may be disposed under the first active layer ACT1, and for example, may be disposed between a substrate (see 100 of FIG. 10) and the first active layer ACT1. The first buffer layer BUF1 may prevent pollution caused by the substrate in a process of forming driving circuits.

The first buffer layer BUF1 may include an insulating material. For example, the first buffer layer BUF1 may include an inorganic insulating material such as SiOx or SiNx. The first buffer layer BUF1 may have a multi-layer structure. For example, the first buffer layer BUF1 may have a multi-layer stack structure including different materials.

As illustrated in FIGS. 3 and 4, the present disclosure may differently set a thickness T1a or T1b of a first portion GI1a of the first gate insulation layer GI1 and a thickness T2 of a second portion GI1b and may differently set a thickness of a third portion GI1c and the thickness T1a or T1b of the first portion GI1a.

For example, in the first gate insulation layer GI1 according to the present disclosure, the thickness T1a or T1b of the first portion GI1a may be greater or less than the thickness T2 of the second portion GI1b, and the thickness of the third portion GI1c may be equal to the thickness T2 of the second portion GI1b.

In the first gate insulation layer GI1, the first portion GI1a may be a portion which does not overlap the first gate electrode G1 (for example, in a plan view) and is adjacent to an edge outer portion EOP of the first gate electrode G1, the second portion GI1b may be a portion which is disposed at a portion overlapping the first gate electrode G1 (for example, in a plan view), and the third portion GI1c may be a portion which is disposed outside the first portion GI1a in the first gate insulation layer GI1 and overlaps the first active layer ACT1.

For example, as illustrated in FIG. 3, in the present disclosure, the thickness T1a of the first portion GI1a may be greater than the thickness T2 of the second portion GI1b in the first gate insulation layer GI1. For example, in the first gate insulation layer GI1, the thickness T1a of the first portion GI1a may be greater than the thickness T2 of the second portion GI1b and may be less than a sum of the thickness T2 of the second portion GI1b and the thickness of the first gate electrode G1.

Here, as in FIG. 3, in the first gate insulation layer GI1, a thickness of the third portion GI1c which is disposed outside the first portion GI1a having the thickness T1a and overlaps the first active layer ACT1 may differ from the thickness T1a of the first portion GI1a, and for example, may be equal to the thickness T2 of the second portion GI1b.

Alternatively, as illustrated in FIG. 4, in the first gate insulation layer GI1, the thickness T1b of the first portion GI1a may be less than the thickness T2 of the second portion GI1b. For example, the thickness T1b of the first portion GI1a may be greater than 1/10 of the thickness T2 of the second portion GI1b and may be less than the thickness T2 of the second portion GI1b.

Here, as in FIG. 4, in the first gate insulation layer GI1, a thickness of the third portion GI1c which is disposed outside the first portion GI1a having the thickness T1b and overlaps the first active layer ACT1 may differ from the thickness T1b of the first portion GI1a, and for example, may be equal to the thickness T2 of the second portion GI1b.

A configuration, where the thickness T1a or T1b of the first portion GI1a is greater or less than the thickness T2 of the second portion GI1b in the first gate insulation layer GI1 of the transistor illustrated in FIGS. 3 and 4, may be applied to a switching transistor.

Therefore, a configuration, where the thickness T1a or T1b of the first portion GI1a is greater or less than the thickness T2 of the second portion GI1b in the first gate insulation layer GI1 included in at least one of the first transistor TR1 in (a) of FIG. 2 and the first and third transistors TR1 and TR3 in (b) of FIG. 2, may be applied.

Alternatively, unlike the illustration of FIG. 2, when another switching transistor other than the first and third transistors TR1 and TR3 is further included in the subpixel SP, a configuration where the thickness T1a or T1b of the first portion GI1a is greater or less than the thickness T2 of the second portion GI1b may be applied to the other switching transistor.

The transistor illustrated in FIG. 5 may be applied to a driving transistor. Accordingly, the transistor illustrated in FIG. 5 may be applied to the second transistor TR2 corresponding to a driving transistor in (a) of FIG. 2.

As illustrated in FIG. 5, a second transistor TR2 which is a driving transistor may supply a driving current, corresponding to a data signal, to a light emitting device OLED and may include a second gate electrode G2, a second active layer ACT2, a second-a source drain electrode SD2a, a second-b source drain electrode SD2b, a second gate insulation layer GI2, a second interlayer insulation layer ILD2, a second buffer layer BUF2, and a light blocking pattern LS, which are disposed in the active area AA.

The second active layer ACT2 may include, for example, an oxide semiconductor material such as IGZO. Alternatively, unlike the first active layer ACT1, the second active layer ACT2 may include low temperature poly-silicone (poly-Si) (LTPS).

The second active layer ACT2 may include a second channel region AC2 and a second-a source drain region ASD2a and a second-b source drain region ASD2b which are disposed with the second channel region AC2 therebetween. The second channel region AC2 may be disposed at a portion overlapping the second gate electrode G2, and the second-a source drain region ASD2a and the second-b source drain region ASD2b may be disposed in a region which does not overlap the second gate electrode G2, outside the second channel region AC2.

The second channel region AC2 may have a doping concentration of dopants which is relatively lower than that of each of the second-a source drain region ASD2a and the second-b source drain region ASD2b and may have an electrical conductivity corresponding to a voltage applied to the second gate electrode G2.

The second-a source drain region ASD2a and the second-b source drain region ASD2b may be relatively higher in doping concentration of dopants than the second channel region AC2, and thus, may each be formed of a conductive region which is high in electrical conductivity.

A second channel length LC2 of the second channel region AC2 may be longer than the first channel length LC1 of the first channel region AC1. That is, the second channel length LC2 between the second-a source drain region ASD2a and the second-b source drain region ASD2b may be longer than the first channel length LC1 between the first-a source drain region ASD1a and the first-b source drain region ASD1b.

The second gate electrode G2 may be disposed apart from the second active layer ACT2 and may overlap the second channel region AC2. The second gate electrode G2 may include a conductive material. For example, the second gate electrode G2 may include metal such as Al, Cr, Cu, Ti, Mo, and W.

The second gate insulation layer GI2 may be disposed between the second gate electrode G2 and the second active layer ACT2 and may insulate the second gate electrode G2 and the second active layer ACT2. The second gate insulation layer GI2 may include at least one of SiOx, SiNx, and SiOxNy. For example, SiOx may include SiO2.

Moreover, the second gate insulation layer GI2 may include the same material as that of the first gate insulation layer GI1 so as to simplify a manufacturing process. However, the present disclosure is not limited thereto.

The second interlayer insulation layer ILD2 may be disposed on the second gate electrode G2. The second interlayer insulation layer ILD2 may extend to an outer portion of the second gate electrode G2. A side surface of the second gate electrode G2 may be covered by the second interlayer insulation layer ILD2. The second interlayer insulation layer ILD2 may extend along the second gate insulation layer GI2. The second interlayer insulation layer ILD2 may include an insulating material. For example, the second interlayer insulation layer ILD2 may include SiOx or SiOxNy.

Moreover, the second interlayer insulation layer ILD2 may include the same material as that of the first interlayer insulation layer ILD1 so as to simplify a manufacturing process. However, the present disclosure is not limited thereto.

Each of the second-a source drain electrode SD2a and the second-b source drain electrode SD2b may be disposed on the second interlayer insulation layer ILD2, and the second-a source drain electrode SD2a and the second-b source drain electrode SD2b may pass through a portion of the second interlayer insulation layer ILD2 and may respectively contact the second-a source drain region ASD2a and the second-b source drain region ASD2b. Each of the second-a source drain electrode SD2a and the second-b source drain electrode SD2b may be insulated from the second gate electrode G2 by the second interlayer insulation layer ILD2.

Each of the second-a source drain electrode SD2a and the second-b source drain electrode SD2b may include at least one of metals such as Al, Cr, Cu, Ti, Mo, and W and may include a material which differs from that of the second gate electrode G2.

The second buffer layer BUF2 may be disposed under the second active layer ACT2, and for example, may be disposed between the substrate and the second active layer ACT2. The second buffer layer BUF2 may prevent pollution caused by the substrate in a process of forming driving circuits.

The second buffer layer BUF2 may include an insulating material. For example, the second buffer layer BUF2 may include an inorganic insulating material such as SiOx or SiNx. The second buffer layer BUF2 may have a multi-layer structure. For example, the second buffer layer BUF2 may have a multi-layer structure including a second-a buffer layer BUF2a and a second-b buffer layer BUF2b.

The light blocking pattern LS may be disposed apart from the second active layer ACT2 in the second buffer layer BUF2. For example, the light blocking pattern LA may be disposed between the second-a buffer layer BUF2a and the second-b buffer layer BUF2b. The light blocking pattern LS may block external light which passes through the substrate and travels to the second active layer ACT2, and thus, may stabilize a driving characteristic of the second transistor TR2.

The light blocking pattern LS may have a size which is greater than that of the second active layer ACT2, at least a portion of the light blocking pattern LS may overlap the second active layer ACT2, and the light blocking pattern LS may be electrically connected to the second active layer ACT2 through one source drain electrode of the second-a source drain electrode SD2a and the second-b source drain electrode SD2b.

The light blocking pattern LS may include a conductive material, and for example, may include metal such as Al, Cr, Cu, Ti, Mo, and W.

In the second gate insulation layer GI2 of the second transistor TR2 which is a driving transistor, a thickness T3a of a portion GI2a which is disposed not to overlap an edge outer portion EOP of the second gate electrode G2 and overlaps the second active layer ACT2 may be equal to a thickness T3b of a portion GI2b overlapping the second gate electrode G2 (e.g., as seen in a plan view).

Unlike the first and third transistors TR1 and TR3, in the second gate insulation layer GI2 of the second transistor TR2, the portion GI2a which does not overlap the second gate electrode G2 and overlaps the second active layer ACT2 may not have a step height of a thickness.

The display apparatus according to embodiments of the present disclosure, as in FIGS. 3 to 5, may be designed in a free form so that a thickness of the first gate insulation layer GI1 has a step height in the first transistor TR1 or the third transistor TR3 which is relatively less channel length than the second transistor TR2, and thus, may be characterized in that the second portion GI1b overlapping the first gate electrode G1 and the first portion GI1a adjacent to the edge outer portion of the first gate electrode G1 have different thicknesses at least.

In detail, as in FIG. 3, in the first gate insulation layer GI1 of the first transistor TR1 or the third transistor TR3, the thickness T1a of the first portion GI1a which is a portion closest to an edge of the first gate electrode G1 may be greater than the thickness T2 of the second portion GI1b, and a thickness of the third portion GI1c may differ from the thickness T1a of the first portion GI1a.

Furthermore, in the first gate insulation layer GI1 of FIG. 3, a thickness of the third portion GI1c disposed outside the first portion GI1a may be less than the thickness T1a of the first portion GI1a. For example, in the first gate insulation layer GI1 of FIG. 3, the thickness of the third portion GI1c may be equal to the thickness T2 of the second portion GI1b.

Alternatively, as in FIG. 4, in the first transistor TR1 or the third transistor TR3, the thickness T1b of the first portion GI1a of the first gate insulation layer GI1 may be less than the thickness T2 of the second portion GI1b.

Furthermore, in the first gate insulation layer GI1 of FIG. 4, the thickness of the third portion GI1c disposed outside the first portion GI1a may be greater than the thickness T1b of the first portion GI1a. For example, in the first gate insulation layer GI1, the thickness of the third portion GI1c may be equal to the thickness T2 of the second portion GI1b. As described above, the first transistor TR1 or the third transistor TR3 may prevent a phenomenon where, as a peak of a Gaussian distribution representing an ion doping concentration is disposed in a layer differing from the first active layer ACT1, ion diffusion occurs in a portion where a peak of a Gaussian distribution occurs, and thus, a valid channel narrows. Accordingly, the operation reliability of a switching transistor may be more enhanced.

In the first gate insulation layer GI1, the first portion GI1a having different thicknesses T1a and T1b may be disposed at a portion of the first gate insulation layer GI1 closest to the edge outer portion of the gate electrode G1 in a region overlapping the first active layer ACT1. Accordingly, a length of a channel formed in the first active layer ACT1 overlapping the second portion GI1b of the first gate insulation layer GI1 may be prevented from being reduced. In the first transistor TR1 or the third transistor TR3, the first portion GI1a of the first gate insulation layer GI1 closest to an edge of the gate electrode G1 may have the thickness T1a which is thicker than the thickness T2 of the second portion GI1b.

In an embodiment of the present disclosure, the thickness T1a or T1b of the first portion GI1a of the first gate insulation layer GI1 may differ from the thickness T2 of the second portion GI1b, and thus, may prevent a valid channel from more narrowing than a designed length, thereby more enhancing the operation reliability of a switching transistor.

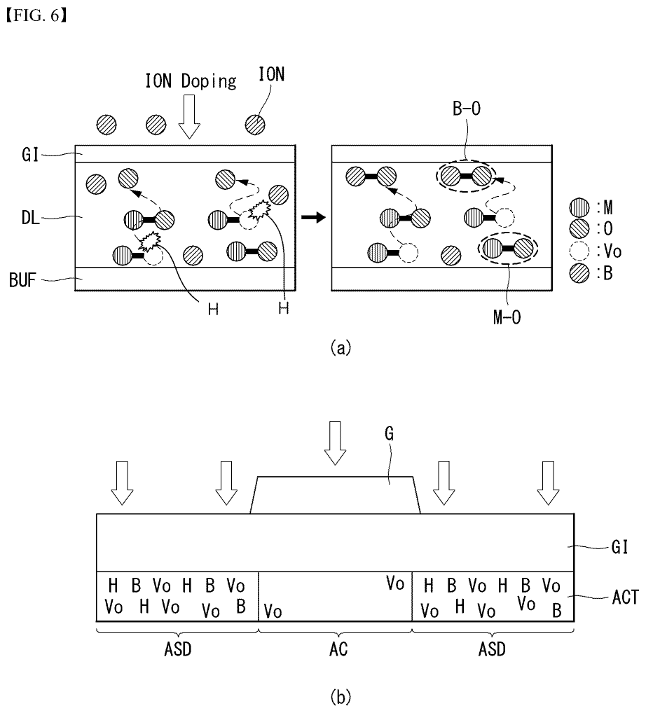

This will be described in more detail with reference to FIGS. 6 to 9.

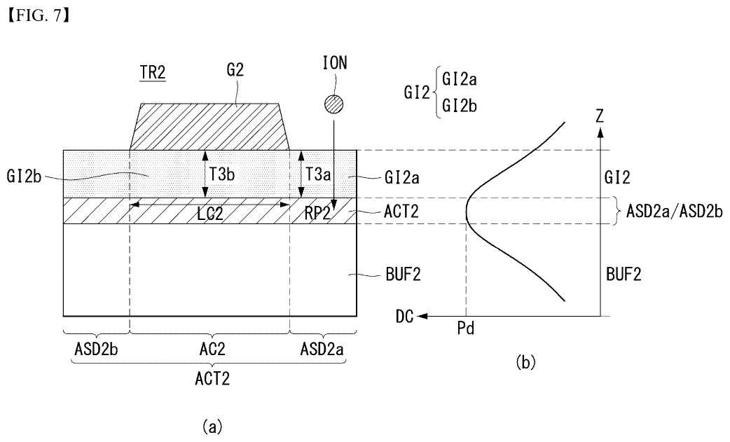

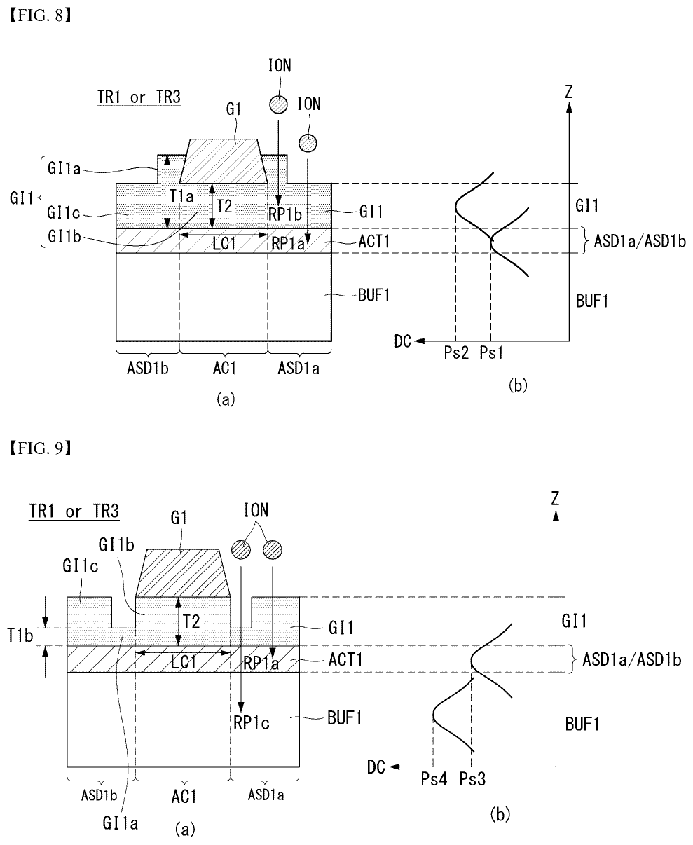

FIG. 6 is a diagram for describing a process of forming a channel region of a transistor, FIG. 7 is a diagram for describing a dopant concentration formed in the second transistor described with reference to FIG. 5, FIG. 8 is a diagram for describing a dopant concentration formed in the first transistor according to the first embodiment described with reference to FIG. 3, and FIG. 9 is a diagram for describing a dopant concentration formed in the first transistor according to the second embodiment described with reference to FIG. 4.

In detail, (a) of FIG. 6 is a diagram for describing a conductivity-providing process of doping an ion on a deposition layer DL in a state where a buffer layer BUF, the deposition layer DL, and a gate insulation layer GI are sequentially stacked, and (b) of FIG. 6 is a diagram for describing a channel formation process of forming a channel through a thermal treatment process.

The deposition layer DL may be formed of the active layer described above with reference to FIGS. 3 to 5 through a conductivity-providing process and a channel formation process. The conductivity-providing process and the channel formation process of FIG. 6 may be applied to all of a switching transistor and a driving transistor.

In (a) of FIG. 6, a structure where a gate electrode G is disposed is omitted, and only the deposition layer is illustrated, but as in (b) of FIG. 6, a conductivity-providing process may be performed in a state where the gate electrode G is formed. In FIG. 6, the deposition layer DL may include an oxide semiconductor material. For example, the deposition layer DL may include an oxide semiconductor material such as IGZO.

In a state where a gate insulation layer GI including hydrogen is provided, for example, a boron ion B is implanted into a position at which a source drain region of the deposition layer DL is to be formed, based on an ion implantation apparatus (not shown), as illustrated in (a) of FIG. 6, the boron ion B may collide with oxygen O bonded to a metal material M, and thus, a bond M-O between metal and oxygen may be broken.

The metal material M where a bond to oxygen O is broken may form a void Vo of oxygen, and the boron ion B may be bonded to bond-broken oxygen O, and thus, may prevent re-bonding M-O between metal and oxygen in the deposition layer DL.

As in (a) of FIG. 6, in a state where the void Vo of oxygen is formed at a position at which a source drain region of the deposition layer DL is to be formed, hydrogen H moving from the gate insulation layer GI may be bonded to the void Vo of oxygen of the deposition layer DL and may be diffused in the deposition layer DL, through a thermal treatment process.

The deposition layer DL may be formed of an active layer ACT of a transistor through the conductivity-providing process and the channel formation process of FIG. 6. That is, both edge outer portions of the gate electrode G in the deposition layer DL may be formed of a source drain region ASD which is high in concentration of boron dopants, and a portion, overlapping the gate electrode G, of the source drain region ASD may be formed of a channel region AC which is relatively low in concentration of boron dopants B.

At this time, as in (a) of FIG. 6, in an ion implantation process, a dopant may be implanted to be slightly inclined instead of being implanted in an accurately vertical direction, and as in (b) of FIG. 6, the void Vo of oxygen may be partially formed in a portion, overlapping both edges, of the gate electrode G.

Therefore, as in (b) of FIG. 6, based on a thermal treatment process, hydrogen may be bonded to the void Vo of oxygen formed in the both edges of the gate electrode G and may travel in a center direction of the channel region AC from both edges of the channel region AC, and thus, an offset region ΔL (not shown) where a concentration of dopants is progressively reduced may be formed.

At this time, the ion implantation apparatus may control an acceleration voltage to control a projection distance of a dopant so that a concentration of dopants is formed to be high in the source drain region ASD, and the projection distance of the dopant by the ion implantation apparatus may vary based on a thickness of the gate insulation layer GI disposed on an active layer. An active layer of each of a driving transistor and a switching transistor may be formed through the conductivity-providing process and the channel formation process described above with reference to FIG. 6.

Here, a length of the channel region may vary based on a length of the offset region ΔL, and the length of the offset region ΔL may vary based on a concentration of dopants doped on the active layer. The concentration of dopants doped on the active layer may vary based on a distribution of dopants doped on the deposition layer DL, and the distribution of dopants may vary based on a projection distance of a dopant implanted in the ion implantation process.

In the present disclosure, based on such a feature, a method may be proposed where a distribution of dopants is controlled by varying a thickness of a gate insulation layer, and thus, a first channel length LC1 of a switching transistor such as the first and third transistors TR1 and TR3 is equal to a designed length. FIG. 7 is a diagram for describing a dopant concentration formed in the second transistor described with reference to FIG. 5, FIG. 8 is a diagram for describing a dopant concentration formed in the first transistor according to the first embodiment described with reference to FIG. 3, and FIG. 9 is a diagram for describing a dopant concentration formed in the first transistor according to the second embodiment described with reference to FIG. 4.

In each of FIGS. 7 to 9, (a) illustrates a cross-sectional structure of a transistor except a source drain electrode, (b) is for describing a Gaussian distribution of dopants implanted into a gate insulation layer, an active layer, and a buffer layer included in the transistor illustrated in (a), one axis DC represents a dopant concentration DC, and the other axis z intersecting one axis represents positions of the gate insulation layer, the active layer, and the buffer layer.

As illustrated in FIG. 7, a driving transistor such as a second transistor TR2 may have a second channel length LC2 which is relatively longer than a switching transistor such as first and third transistors TR1 and TR3.

In the second transistor TR2 having the second channel length LC2 which is relatively long as in FIG. 7, because there is a residual space for forming a channel, even when a distribution of dopants formed in the second-a and second-b source drain regions ASD2a and ASD2b of a second active layer ACT2, a desired channel length may be sufficiently formed in the second transistor TR2, and the second transistor TR2 may operate with a desired threshold voltage. That is, when doping a dopant by using a second gate electrode G2 as a mask, a width of the second gate electrode G2 overlapping the second active layer ACT2 may be long, and thus, despite the degree to which dopants are diffused to an inner region of the second active layer ACT2 from an edge of the second gate electrode G2, because the degree of diffusion on the width of the second gate electrode G2 is small, a valid channel may be hardly reduced or may decrease.

Therefore, it may not be needed to differently form thicknesses of a first portion GI2a and a second portion GI2b of the second gate insulation layer GI2 so as to form the second transistor TR2, and as in (a) of FIG. 7, a thickness T3a of the first portion GI2a disposed not to overlap an edge outer portion of the second gate electrode G2 in the second gate insulation layer GI2 may be equal to a thickness T3b of the second portion GI2b disposed at a portion overlapping the second gate electrode G2.

In an ion implantation process of forming the second transistor TR2, a projection distance RP2 of an ion may be controlled so that a Gaussian distribution of doped dopants has a peak Pd in the second active layer ACT2. Accordingly, as in (b) of FIG. 7, a position at which a peak Pd is formed in a Gaussian distribution of dopants doped on the second transistor TR2 may be in the second-a and second-b source drain regions ASD2a and ASD2b of the second active layer ACT2, and a dopant concentration in the second gate insulation layer GI2 or a second buffer layer BUF2 may have a dopant concentration which is lower than that of each of the second-a and second-b source drain regions ASD2a and ASD2b.

On the other hand, a switching transistor such as the first and third transistors TR1 and TR3 may have a first channel length LC1 which is relatively short. For example, in the first and third transistors TR1 and TR3, when an offset region ΔL varies based on dopant diffusion when doping dopants in the first channel length LC1 which is short, a valid channel may decrease, a variation rate (ΔL/LC1) of the offset region ΔL on the first channel length LC1 designed may increase, and a variation rate (ΔL/LC2) of the offset region ΔL on the second channel length LC2 may increase in a driving transistor where a channel length is long. Therefore, the switching transistor may be greater in tendency, where a threshold voltage Vth of a transistor is shifted in a negative (−) direction by an influence of dopant diffusion, than the driving transistor. Also, when a threshold voltage is shifted in a negative (−) direction, an off current may increase, and due to this, the operation reliability of a transistor may be reduced. That is, when an actually formed channel length differs from a designed channel length, a threshold voltage Vth of a transistor may vary, and due to this, the operation reliability of a transistor may be reduced.

Moreover, when an active layer includes an oxide semiconductor material, the active layer may sufficiently include indium (In), and thus, when implanting dopants, a void Vo of oxygen may be easily formed, whereby the diffusion of a conductive region may easily occur.

Based on this, the present disclosure may control a dopant distribution in a device so that a channel length actually formed in a switching transistor is formed to be maximally equal to a designed channel length.

Accordingly, in the present disclosure, a position of a peak of a Gaussian distribution of dopants doped on the first transistor TR1 may differ from a position of a peak of a Gaussian distribution of dopants doped on the second transistor TR2.

In detail, a position at which a peak is formed in a Gaussian distribution of dopants doped on the first transistor TR1 may be in a film or a layer which differs from the first active layer ACT1, and a position at which a peak Pd is formed in a Gaussian distribution of dopants doped on the second transistor TR2 may be in the second active layer ACT2.

That is, in the present disclosure, a thickness T1a or T1b of a first portion GI1a of a first gate insulation layer GI1 of a switching transistor such as the first and third transistors TR1 and TR3 may differ from a thickness T2 of a second portion GI1b, and a thickness of a third portion GI1c may differ from the thickness T1a or T1b of the first portion GI1a, and thus, a projection distance of a dopant may be adjusted to be dualized. Accordingly, a dopant distribution in a device may be controlled, and thus, a channel length actually formed in a switching transistor may be maximally equal to a designed channel length.

As described above, the first portion GI1a of the first gate insulation layer GI1 may denote a portion which does not overlap the first gate electrode G1 and is closest to an edge outer portion of the first gate electrode G1, the second portion GI1b may denote a portion which overlaps the first gate electrode G1, and the third portion GI1c may denote a portion which is disposed outside the first portion GI1a in the first gate insulation layer GI1 and overlaps the first active layer ACT1.

In detail, as in a first embodiment of the first transistor TR1 illustrated in FIG. 8, the thickness T1a of the first portion GI1a of the first gate insulation layer GI1 may be greater than the thickness T2 of the second portion GI1b. Also, as described above with reference to FIG. 3, a thickness of the third portion GI1c in the first gate insulation layer GI1 may be less than the thickness T1a of the first portion GI1a, and for example, may be equal to the thickness T2 of the second portion GI1b.

Therefore, as illustrated in FIG. 8, in an ion implantation process, the present disclosure may perform control so that ion projection distances of first and second portions are dualized to be RP1a and RP1b.

That is, the ion projection distance RP1b may be controlled so that an implanted ion stays in the first gate insulation layer GI1, based on the thickness T1a of the first portion GI1a which is relatively greater than the thickness of the third portion GI1c, and in the third portion GI1c, the ion projection distance RP1a may be controlled so that an implanted ion stays in the first active layer ACT1, based on a thickness which is relatively less than the thickness T1a of the first portion GI1a.

Therefore, in a region overlapping the first portion GI1a, a peak of a Gaussian distribution of doped dopants may be in the first gate insulation layer GI1 which is a layer differing from the first active layer ACT1.

In detail, the first gate insulation layer GI1 may have a peak Ps2 of a Gaussian distribution of dopants doped on the first active layer ACT1 in the first portion GI1a, and the first active layer ACT1 may have a peak Ps1 of a Gaussian distribution of dopants doped on the first active layer ACT1 in a portion which is spaced apart from an edge of the first gate electrode G1 by the first portion GI1a.

Accordingly, in a region of the first active layer ACT1 overlapping the first portion GI1a of the first gate insulation layer GI1, a dopant distribution may be controlled so that a dopant concentration is lower than a concentration of dopants doped on the first gate insulation layer GI1.

Moreover, as in a second embodiment of the first transistor TR1 illustrated in FIG. 9, the thickness T1b of the first portion GI1a of the first gate insulation layer GI1 may be less than the thickness T2 of the second portion GI1b, and a thickness of the third portion GI1c may be greater than the thickness T1b of the first portion GI1a. Also, as described above with reference to FIG. 4, a thickness of the third portion GI1c which is disposed outside the first portion GI1a having a thickness T1b in the first gate insulation layer GI1 and overlaps the first active layer ACT1 may be greater than the thickness T1b of the first portion GI1a, and for example, may be equal to the thickness T2 of the second portion GI1b.

Therefore, in an ion implantation process, the present disclosure may perform control so that ion projection distances of first and second portions are dualized to be RP1a and RP1c. That is, the ion projection distance RP1c may be controlled so that an implanted ion stays in the first buffer layer BUF1, based on the thickness T1b of the first portion GI1a which is relatively less than the thickness of the third portion GI1c, and in the third portion GI1c, the ion projection distance RP1a may be controlled so that an implanted ion stays in the first active layer ACT1, based on a thickness which is relatively greater than the thickness T1b of the first portion GI1a.

Therefore, in a region overlapping the first portion GI1a, a peak of a Gaussian concentration of doped dopants may be in the first buffer layer BUF1 which is a layer differing from the first active layer ACT1.

In detail, the first buffer layer BUF1 may have a peak Ps4 of a Gaussian distribution of dopants doped on the first active layer ACT1 in a region overlapping the first portion GI1a, and the first active layer ACT1 may have a peak Ps3 of a Gaussian distribution of dopants doped on the first active layer ACT1 in a portion which is spaced apart from an edge of the first gate electrode G1 by the first portion GI1a.

Accordingly, in a region of the first active layer ACT1 overlapping the first portion GI1a of the first gate insulation layer GI1, a dopant distribution may be controlled so that a dopant concentration is lower than a concentration of dopants doped on the first buffer layer BUF1.

The present disclosure may control a distribution so that a dopant concentration of the first active layer ACT1 in a region overlapping the first portion GI1a is relatively lower than a dopant concentration of the first buffer layer BUF1 or the first gate insulation layer GI1, and thus, may minimize a width of an offset region ΔL formed between a first channel region AC1 and the first-a and first-b source drain regions ASD1a and ASD1b, whereby a channel length actually formed in a switching transistor may be formed to be maximally equal to a designed channel length.

Accordingly, in forming a switching transistor including an oxide semiconductor, the present disclosure may prevent a channel length from being reduced, and thus, a threshold voltage (Vth) of an initial transistor may be prevented from being shifted in a negative (−) direction, thereby preventing a degradation.

Moreover, the present disclosure may differently set a thickness of a gate insulation layer and may perform control so that a peak of a Gaussian distribution of dopants is disposed in a layer which differs from an active layer, and thus, may prevent a length of a valid channel from being reduced by the diffusion of dopants based on thermal treatment.

The present disclosure may not add a separate element and may differently set a thickness of the gate insulation layer, and thus, may enhance the driving stability and reliability of a transistor and a display apparatus, thereby implementing environment, social, and governance (ESG).

Hereinafter, an example of a display apparatus to which a switching transistor such as the first transistor TR1 and a driving transistor such as the second transistor TR2 described above are applied will be described.

FIG. 10 is a diagram for describing an embodiment of a display apparatus to which first and second transistors are applied.

In FIG. 10, the substrate 100 may include a plastic material having flexibility and may have a flexible characteristic, and moreover, may include a glass material of a thin thickness having flexibility.

The substrate 100 may have a multi-layer structure including an insulating material. For example, as illustrated in FIG. 10, the substrate 100 may have a structure where a first substrate layer 101, a substrate insulation layer 102, and a second substrate layer 103 are sequentially stacked, and the first and second substrate layers 101 and 103 may include a polymer material such as polyimide (PI). The substrate insulation layer 102 may include an insulating material.

A first insulation layer 110 may be disposed in an active area AA and a non-active area NA of the substrate 100. The first insulation layer 110 may be referred to as a buffer layer. The first insulation layer 110 may be disposed on the substrate 100, may protect structures on the substrate 100 vulnerable to water transmission from water penetrating through the substrate 100, and may planarize a surface of the substrate 100. The first gate insulation layer 110 may be formed of an inorganic single layer, or as in FIG. 10, the insulation layer 110 may include a first-a insulation layer 111 and a first-b insulation layer 112, where a plurality of inorganic layers are formed in a multi-layer structure. For example, each of the first-a insulation layer 111 and the first-b insulation layer 112 may include one or more inorganic layers of SiOx, SiNx, and SiOxNy.

A second insulation layer 130 may be disposed on the first insulation layer 110. The second insulation layer 130 may function as an interlayer insulation layer of each transistor (not shown) configuring a gate driver (not shown) disposed in the non-active area NA. The second insulation layer 130 may include an inorganic material. The inorganic material may include, for example, SiNx.

To enhance a reaction speed of a first transistor TR1, a bottom gate electrode BOT connected to a first gate electrode G1 may be provided between the first insulation layer 110 and the second insulation layer 120. The bottom gate electrode BOT may include a metal material which differs from that of the first gate electrode G1 and may include the same material as that of a gate electrode of another transistor which is formed on the same layer as the bottom gate electrode BOT.

A device buffer layer 140 may be provided on the second insulation layer 130. The device buffer layer 140 may fully cover the active area AA of the substrate 100 and may include an insulating material. For example, the device buffer layer 140 may include an inorganic insulating material such as SiOx or SiNx. The device buffer layer 140, for example, as in FIG. 10, may include a multi-layer structure where a first device buffer layer 141 and a second device buffer layer 142 are stacked. The first device buffer layer 141 and the second device buffer layer 142 may include the same material, or may include different materials.

A first active layer ACT1 of a first transistor TR1 which is a switching transistor and a second active layer ACT2 of a second transistor TR2 which is a driving transistor may be disposed on the device buffer layer 140. As in FIG. 10, when the first and second transistors TR1 and TR2 are disposed on the same device buffer layer 140, a manufacturing process may be more simplified.

However, all switching transistors and a driving transistor may not be formed on the same device buffer layer 140, and the present disclosure is not limited thereto. For example, some of a plurality of switching transistors and a driving transistor may be formed on the same device buffer layer 140, or a cross-sectional structure where only one transistor of a switching transistor and a driving transistor is formed on the device buffer layer 140 may be variously modified.

As in FIG. 10, when first and second active layers ACT1 and ACT2 of the first and second transistors TR1 and TR2 are disposed on the same device buffer layer 140, the device buffer layer 140 may be used as the first buffer layer BUF1 of the first transistor TR1 described above with reference to FIGS. 3 and 4 and the second buffer layer BUF2 of the second transistor TR2 described above with reference to FIG. 5.

When the device buffer layer 140 is used as the second buffer layer BUF2 of the second transistor TR2, the second-b buffer layer BUF2b of the second transistor TR2 may be the same as the second device buffer layer 142, and the second-a buffer layer BUF2a of the second transistor TR2 may be the same as the first device buffer layer 141.

The first and second transistors TR1 and TR2 may be disposed on the device buffer layer 140.

The first transistor TR1 may include a first active layer ACT1, a first gate electrode G1, a first-a source drain electrode SD1a, a first-b source drain electrode SD1b, a first gate insulation layer GI1, and a first interlayer insulation layer ILD1, which are disposed on the device buffer layer 140.

In FIG. 10, a case where a thickness T1a of a first portion GI1a is greater than a thickness T2 of a second portion GI1b in the first gate insulation layer GI1 included in the first transistor TR1 is illustrated for example. However, this may be an embodiment, and in the first transistor TR1, thicknesses of the first and second portions in the first gate insulation layer GI1 and a structure of each of the first active layer ACT1, the first gate electrode G1, the first-a source drain electrode SD1a, the first-b source drain electrode SD1b, the first gate insulation layer GI1(150 in FIG. 10), and the first interlayer insulation layer ILD1(200 in FIG. 10) may be the same as the descriptions of FIGS. 3, 4, 8, and 9.

Therefore, a thickness T1a or T1b of the first portion GI1a in the first gate insulation layer GI1 included in the first transistor TR1 may be greater or less than the thickness T2 of the second portion GI1b, and a peak Ps1 or Ps3 of a Gaussian distribution of dopants doped on a first-a source drain region ASD1a or a first-b source drain region ASD1b may be less than a peak Ps2 of a Gaussian distribution of dopants doped on the first gate insulation layer GI1, or may be less than a peak Ps4 of a Gaussian distribution of dopants doped on a first buffer layer BUF1.

The second transistor TR2 may include a second active layer ACT2, a second gate electrode G2, a second-a source drain electrode SD2a, a second-b source drain electrode SD2b, a second gate insulation layer GI2 (150 in FIG. 10), and a second interlayer insulation layer ILD2 (200 in FIG. 10), which are disposed on the device buffer layer 140. A light blocking pattern LS electrically connected to one of the second-a source drain electrode SD2a and the second-b source drain electrode SD2b of the second transistor TR2 may be provided between the first and second device buffer layers 141 and 142.

The second active layer ACT2, the second gate electrode G2, the second-a source drain electrode SD2a, the second-b source drain electrode SD2b, the second gate insulation layer GI2, the second interlayer insulation layer ILD2, and the light blocking pattern LS of the second transistor TR2 may be the same as the descriptions of FIGS. 5 and 7.

Therefore, a second channel length LC2 formed in the second active layer ACT2 in the second transistor TR2 may be longer than a first channel length LC1 formed in the first active layer ACT1 in the first transistor TR1.

Moreover, as described above with reference to FIGS. 5 and 7, a thickness of a portion disposed not to overlap an edge outer portion of the second gate electrode G2 in the second gate insulation layer GI2 may be equal to that of a portion disposed at a portion overlapping the second gate electrode G2.

A position of a maximum peak Pd of a Gaussian distribution of dopants doped on the second transistor TR2 may differ from a position of a maximum peak Ps1 or Ps3 of a Gaussian distribution of dopants doped on the first transistor TR1.

Moreover, as illustrated in FIG. 10, when the first and second transistors TR1 and TR2 are provided on the same device buffer layer 140, the first gate insulation layer GI1 of the first transistor TR1 and the second gate insulation layer GI2 of the second transistor TR2 may be formed of the same gate insulation layer 150. Accordingly, the first gate insulation layer GI1 of the first transistor TR1 and the second gate insulation layer GI2 of the second transistor TR2 may include the same material, and a manufacturing process may be simplified.

Moreover, a thickness of a gate insulation layer between the first active layer ACT1 and the first gate electrode G1 included in the first transistor TR1 may be equal to that of a gate insulation layer between the second active layer ACT2 and the second gate electrode G2 included in the second transistor TR2. However, the present disclosure is not limited thereto.

Moreover, when the first and second transistors TR1 and TR2 are provided on the same device buffer layer 140, as illustrated in FIG. 10, the first interlayer insulation layer ILD1 of the first transistor TR1 and the second interlayer insulation layer ILD2 of the second transistor TR2 may be formed of the same interlayer insulation layer 200. Accordingly, the first interlayer insulation layer ILD1 of the first transistor TR1 and the second interlayer insulation layer ILD2 of the second transistor TR2 may include the same material, and a manufacturing process may be simplified.

As in FIG. 10, when the first and second transistors TR1 and TR2 are provided on the same device buffer layer 140, the first buffer layer BUF1 and the second buffer layer BUF2, the first gate insulation layer GI1 and the second gate insulation layer GI2, and the first interlayer insulation layer ILD1 and the second interlayer insulation layer ILD2 may be formed of the same materials by using the same process, and thus, a process step may be implemented. Accordingly, a process step may be simplified, production energy for producing a display apparatus may be reduced, and the occurrence of a greenhouse gas caused by a manufacturing process may decrease, thereby implementing ESG.

In each pixel area, a first planarization layer 300 and a second planarization layer 400 may be sequentially stacked between a light emitting device OLED and a circuit element such as the first and second transistors TR1 and TR2. For example, a first electrode 610 (for example, an anode electrode), an emission layer 620, and a second electrode 630 (for example, a cathode electrode) of each pixel area PA may be sequentially stacked on the second planarization layer 400 of a corresponding pixel area PA.

The first planarization layer 300 and the second planarization layer 400 may remove a step height caused by a driving circuit. For example, an upper surface of the second planarization layer 400 facing the light emitting device OLED of each pixel area PA may be a flat surface. The first planarization layer 300 and the second planarization layer 400 may include an insulating material. The first planarization layer 300 and the second planarization layer 400 may include a material having high flowability. For example, the first planarization layer 300 and the second planarization layer 400 may include an organic insulating material. The second planarization layer 400 may include a material which differs from that of the first planarization layer 300. Accordingly, in the display apparatus according to an embodiment of the present disclosure, a step height caused by driving circuits may be effectively removed.

A center electrode CE2 of the second transistor TR2 may be disposed between the first planarization layer 300 and the second planarization layer 400 of each pixel area PA. Also, depending on the case, a center electrode CE1 of the first transistor TR1 may be disposed for a circuit configuration with another transistor (not shown), between the first planarization layer 300 and the second planarization layer 400.

The center electrode CE2 of the second transistor TR2 may be electrically connected to one source drain electrode of the second-a source drain electrode SD2a and the second-b source drain electrode SD2b of the second transistor TR2. In FIG. 10, a case where the second-a source drain electrode SD2a is connected to the center electrode CE2 of the second transistor TR2 is illustrated for example.

Moreover, the center electrode CE2 of the second transistor TR2 may be electrically connected to the first electrode 610 of a light emitting device 600. To this end, the first electrode 610 of the light emitting device 600 may pass through the second planarization layer 400 and may be connected to the center electrode CE2 of the second transistor TR2. The center electrode CE2 of the second transistor TR2 may include a conductive material. For example, the center electrode CE2 of the second transistor TR2 may include metal such as Al, Cr, Cu, Ti, Mo, and W. The center electrode CE2 of the second transistor TR2 may include a material which differs from those of the second-a source drain electrode SD2a, the second-b source drain electrode SD2b, and the first electrode 610.

A bank insulation layer 500 may be disposed on the second planarization layer 400 of each pixel area PA. The bank insulation layer 500 may include an insulating material. For example, the bank insulation layer 500 may include an organic insulating material.

The bank insulation layer 500 may include a material which differs from that of each of the first planarization layer 300 and the second planarization layer 400. The bank insulation layer 500 may cover an edge of the first electrode 610. The emission layer 620 and the second electrode 630 may be stacked on a partial region of the first electrode 610 exposed by the bank insulation layer 500. For example, the bank insulation layer 500 may define an emission region in each pixel area PA.

The light emitting device 600 may be disposed in the emission region and may include the first electrode 610, the emission layer 620, and the second electrode 630.

In the light emitting device (OLED) 600, the first electrode 610 may include a conductive material. The first electrode 610 may have a high reflectance. For example, the first electrode 610 may include metal such as Al and silver (Ag). The first electrode 610 may have a multi-layer structure. For example, the first electrode 610 may have a structure where a reflective electrode including metal is disposed between transparent electrodes including a transparent conductive material such as indium tin oxide (ITO) or indium zinc oxide (IZO).

The emission layer 620 may generate light of luminance corresponding to a voltage difference between the first electrode 610 and the second electrode 630. For example, the emission layer 620 may include an emission material layer (EML) including an emission material. The emission material may include an organic material, an inorganic material, or a hybrid material. For example, the emission layer 620 may include an emission material layer including an organic material.

The emission layer 620 may include at least one of a first emission common layer (not shown) disposed between first electrodes 610 and a second emission common layer (not shown) disposed between second electrodes 630. Each of the first emission common layer (not shown) and the second emission common layer (not shown) may include at least one of a hole injection layer (HIL), a hole transport layer (HTL), an electron transport layer (ETL), and an electron injection layer (EIL).

The second electrode 630 may include a conductive material. The second electrode 630 may include a material which differs from that of the first electrode 610. For example, the second electrode 630 may be a transparent electrode including a transparent conductive material such as ITO or IZO. The second electrode 630 may have a transmittance which is higher than that of the first electrode 610. Accordingly, in the display apparatus according to an embodiment of the present disclosure, light generated by the emission layer 620 may be emitted through the second electrode 630.

An encapsulation member 700 may be disposed on the light emitting device (OLED) 600 and the bank insulation layer 500 of each pixel area PA. The encapsulation member 700 may prevent the damage of the light emitting devices 600 caused by an external impact and water. The encapsulation member 700 may have a multi-layer structure. For example, the encapsulation member 700 may be provided by alternately stacking an encapsulation layer including an inorganic insulating material and an encapsulation layer including an organic insulating material. For example, the encapsulation layer including the inorganic insulating material may be provided between encapsulation layers including the organic insulating material.

Therefore, in the display apparatus according to an embodiment of the present disclosure, the damage of the light emitting device (OLED) 600 caused by an external impact and water may be effectively prevented. A step height caused by the light emitting device (OLED) 600 of each pixel area PA may be removed by the encapsulation member 700. For example, an upper surface of the encapsulation member 700 opposite to the device substrate 100 may be a flat surface.

In FIG. 10, a case where a first transistor TR1 which is a switching transistor and a second transistor TR2 which is a driving transistor are connected to a light emitting device OLED is illustrated for example, but the present disclosure is not limited thereto.

As described above with reference to (b) of FIG. 2, when a third transistor TR3 which is a switching transistor is provided, the second transistor TR2 may be electrically connected to the third transistor TR3, and the third transistor TR3 may be electrically connected to the light emitting device OLED.

Moreover, in an embodiment of the present disclosure, a case where the thickness T1a or T1b of the first portion GI1a of the first gate insulation layer GI1 of a switching transistor such as the first transistor TR1 included in the active area AA differs from the thickness T2 of the second portion GI1b has been described for example, but the present disclosure is not limited thereto.

For example, in FIG. 1, a GIP driver (for example, a gate driving circuit) for supplying a control signal to a subpixel SP may be provided in the non-active area NA of the substrate 100, and a configuration where the thickness T1a or T1b of the first portion GI1a of the gate insulation layer differs from the thickness T2 of the second portion GI1b may also be applied to a switching element included in the driving circuit.

As described above, in the display apparatus according to an embodiment of the present disclosure, the thickness T1a or T1b of the first portion GI1a of the gate insulation layer may differ from the thickness T2 of the second portion GI1b in a switching transistor having a short channel length, and thus, a desired channel length may be formed, thereby enhancing the driving stability and reliability of a switching transistor.

Embodiments of the present disclosure may differently set a thickness of a first portion and a thickness of a second portion in a gate insulation layer of a switching transistor, and thus, may control a distribution of an element, thereby more enhancing the driving stability and reliability of a switching transistor.

Embodiments of the present disclosure provide a display apparatus in which a reduction in length of a valid channel may be prevented when forming a transistor including an oxide semiconductor, and thus, a threshold voltage (Vth) of an initial transistor may be prevented from being shifted in a negative (−) direction.

Embodiments of the present disclosure provide a transistor and a display apparatus including the same, in which a thickness of a gate insulation layer may be differently set, a peak of a Gaussian distribution of dopants may be controlled to be disposed in a layer which differs from an active layer, and a length of a valid channel may be prevented from being reduced by the diffusion of dopants based on thermal treatment.

Embodiments of the present disclosure may not add a separate element and may differently set a thickness of a gate insulation layer, and thus, may enhance the driving stability and reliability of a transistor and a display apparatus and may decrease power consumption, thereby implementing ESG.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including an active area and a non-active area;
a first transistor disposed in the active area and including a first gate electrode, a first-a source drain electrode, a first-b source drain electrode, and a first active layer; and
a first gate insulation layer disposed between the first gate electrode and the first active layer,
wherein a thickness of a first portion, which does not overlap the first gate electrode and is adjacent to an edge outer portion of the first gate electrode, differs from a thickness of a second portion overlapping the first gate electrode in the first gate insulation layer.

2. The display apparatus of claim 1, wherein a thickness of a third portion, which is disposed outside the first portion and overlaps the first active layer, differs from a thickness of the first portion in the first gate insulation layer.

3. The display apparatus of claim 2, wherein the first active layer comprises a source drain region where a dopant is present in a region which does not overlap the first gate electrode, and
in a region overlapping the first portion, a peak of a Gaussian distribution of a doping concentration of the dopant is disposed in a layer which differs from the first active layer.

4. The display apparatus of claim 2, wherein a thickness of the first portion is greater than a thickness of the second portion, and a thickness of the third portion is less than the thickness of the first portion, and
a peak of a Gaussian distribution of dopants doped into the first active layer is located within a region of the first gate insulation layer corresponding to the first portion.

5. The display apparatus of claim 2, wherein, in the first active layer, a peak of a Gaussian distribution of dopants doped on the first active layer is disposed at a portion spaced apart from an edge of the first gate electrode by the first portion.

6. The display apparatus of claim 4, wherein the thickness of the first portion is greater than the thickness of the second portion and is less than a sum of thicknesses of the second portion and the first gate electrode.

7. The display apparatus of claim 2, further comprising a first buffer layer between the substrate and the first active layer,
wherein a thickness of the first portion is less than a thickness of the second portion, and a thickness of the third portion is greater than the thickness of the first portion, and
the first buffer layer has a peak of a Gaussian distribution of dopants doped on the first active layer in a region overlapping the first portion.

8. The display apparatus of claim 7, wherein the thickness of the first portion is less than the thickness of the second portion and is greater than 1/10 of the thickness of the second portion.

9. The display apparatus of claim 1, wherein the first active layer comprises an oxide semiconductor.

10. The display apparatus of claim 1, further comprising a second transistor disposed in the active area and including a second gate electrode, a second-a source drain electrode, a second-b source drain electrode, and a second active layer,
wherein a length of a channel formed in the first active layer in the first transistor is shorter than a length of a channel formed in the second active layer in the second transistor.

11. The display apparatus of claim 10, further comprising a second gate insulation layer disposed between the second gate electrode and the second active layer,
wherein a thickness of a portion of the second gate insulation layer that is disposed outside the second gate electrode and does not overlap the second gate electrode is equal to a thickness of a portion that overlaps the second gate electrode.

12. The display apparatus of claim 10, wherein a position of a maximum peak of a Gaussian distribution of dopants doped on the first transistor differs from a position of a maximum peak of a Gaussian distribution of dopants doped on the second transistor.

13. The display apparatus of claim 10, wherein a position at which a maximum peak is formed in a Gaussian distribution of dopants doped in the first transistor is disposed in a layer different from the first active layer, and
a position at which a maximum peak is formed in a Gaussian distribution of dopants doped in the second transistor is disposed in the second active layer.

14. The display apparatus of claim 10, further comprising a light emitting device disposed on the first and second transistors in the active area and including a first electrode, an organic emission layer, and a second electrode, and
one of the first or second transistors is electrically connected to the first electrode.

15. A transistor comprising:
a first active layer including an oxide semiconductor material and including a first channel region and a first-a source drain region and a first-b source drain region provided with the channel region therebetween;
a first gate electrode disposed on the first active layer to overlap the first channel region;
a first-a source drain electrode and a first-b source drain electrode respectively connected to the first-a source drain region and the first-b source drain region; and
a first gate insulation layer disposed between the first gate electrode and the first active layer,
wherein a thickness of a first portion, which does not overlap the first gate electrode and is adjacent to an edge of the first gate electrode, differs from a thickness of a second portion disposed at a portion overlapping the first gate electrode in the first gate insulation layer.

16. The transistor of claim 15, wherein a thickness of a third portion, which is disposed outside the first portion and overlaps the first active layer, differs from a thickness of the first portion in the first gate insulation layer.

17. The transistor of claim 15, wherein dopants are doped in the first-a and first-b source drain regions in the first active layer, and
in a region overlapping the first portion, a peak of a Gaussian distribution representing the doping concentration of the dopants is disposed in a layer different from the first active layer.

18. The transistor of claim 16, wherein a thickness of the first portion is greater than a thickness of the second portion, and a thickness of the third portion is less than the thickness of the first portion, and
a peak of a Gaussian distribution of dopants doped into the first active layer is located within a region of the first gate insulation layer corresponding to the first portion.

19. The transistor of claim 16, wherein, in the first active layer, a peak of a Gaussian distribution of dopants doped on the first active layer is disposed at a portion spaced apart from an edge of the first gate electrode by the first portion.

20. The transistor of claim 16, further comprising a substrate, and a first buffer layer between the substrate and the first active layer,
wherein a thickness of the first portion is less than a thickness of the second portion, and a thickness of the third portion is greater than the thickness of the first portion, and
the first buffer layer has a peak of a Gaussian distribution of dopants doped on the first active layer in a region overlapping the first portion.
